(19) United States
(12) Patent Application Publication
(10) Pub. No.: US 2010/0284434 A1
(43) Pub. Date: Nov. 11, 2010

(54) EDGE EMITTING SEMICONDUCTOR LASER CHIP HAVING AT LEAST ONE CURRENT BARRIER

(75) Inventors: Harald Koenig, Bernhardswald (DE); Christian Lauer, Regensburg (DE); Martin Mueller, Regenstauf (DE); Martin Reufer, Rohrbach (DE); Bernd Mayer, Regensburg (DE)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: OSRAM Opto Semiconductors GmbH, Regensburg (DE)

(21) Appl. No.: 12/810,644

(22) PCT Filed: Dec. 15, 2008
(86) PCT No.: PCT/DE08/02085

§ 371 Date: Jul. 20, 2010

(30) Foreign Application Priority Data
Dec. 27, 2007 (DE) 10 2007 062 789.2
Mar. 13, 2008 (DE) 10 2008 014 093.7

(51) Int. Cl. H01S 5/02; H01S 5/10

(52) U.S. Cl. 372/46.01

(57) ABSTRACT

An edge emitting semiconductor laser chip includes at least one contact strip, wherein the contact strip has a width B, an active zone, in which electromagnetic radiation is generated during the operation of the semiconductor laser chip, and at least two current barriers, arranged on different sides of the contact strip and extending along the contact strip, wherein the largest distance V between at least one of the current barriers and the contact strip is chosen in such a way that the ratio of the largest distance V to the width B is V/B>1.

### RELATED APPLICATIONS

This is a §371 of International Application No. PCT/DE2008/002085, with an inter-national filing date of Dec. 15, 2008 (WO 2009/082995 A1, published Jul. 9, 2009), which is based on German Patent Application Nos. 10 207 062 789.2, filed Dec. 27, 2007, and 10 2008 014 093.7, filed Mar. 13, 2008, the subject matter of which is incorporated by reference.

### TECHNICAL FIELD

This disclosure relates to an edge emitting semiconductor laser chip having at least one current barrier.

### BACKGROUND

U.S. Pat. No. 6,947,464 B2 describes an edge emitting semiconductor laser chip and also a method for producing an edge emitting semiconductor laser chip. However, it could be helpful to provide an edge emitting semiconductor laser chip which is suitable for generating laser radiation having reduced beam divergence, in particular, in the slow-axis direction.

### SUMMARY

We thus provide an edge emitting semiconductor laser chip, the edge emitting semiconductor laser chip comprising at least one contact strip. The contact strip of the semiconductor laser chip is provided for the injection of current into the semiconductor laser chip. The contact strip is formed, for example, by metalization on an outer surface of the semiconductor laser chip. In this case, the contact strip has a width B.

The edge emitting semiconductor laser chip may comprise an active zone. During the operation of the semiconductor laser chip, electromagnetic radiation is generated in the active zone. The active zone contains, for example, one or more quantum well structures which provide optical amplification upon injection of electric current into the active zone by means of stimulated recombination.

The designation quantum well structure encompasses, in particular, any structure in which charge carriers can experience a quantization of their energy states as a result of confinement. In particular, the designation quantum well structure does not include any indication about the dimensionality of the quantization. It therefore encompasses, inter alia, quantum wells, quantum wires and quantum dots and any combination of these structures.

The edge emitting semiconductor laser chip may comprise at least two current barriers. The current barriers prevent lateral current spreading such that electric current impressed by a contact strip does not spread in such a way that the entire active zone is energized, rather current is applied only to a specific predeterminable segment of the active zone with the aid of the current barriers. For this purpose, the current barriers prevent, for example, uncontrolled spreading of the current in the semiconductor layers which are arranged between the contact strip and the active zone. The current spreading is delimited by the current barriers.

The current barriers are preferably arranged on different sides of the contact strip and extend along the contact strip. If the edge emitting semiconductor laser chip has more than one contact strip, then each contact strip is preferably assigned at least two current barriers which extend along the contact strip. In this case, it is also possible for exactly one current barrier to be situated between two contact strips. In this case, however, the current barriers do not have to extend over the entire length of the contact strip.

The largest distance V between at least one of the current barriers and the contact strip may be chosen in such a way that the ratio of the largest distance V to the width B of the contact strip is V/B>1.0. Preferably, the largest distance V between each of the two current barriers and the contact strip is chosen in such a way that the ratio of the largest distance V to the width B of the contact strip is V/B>1.0. In this case, the distance is measured from the outer edge of the contact strip to the inner edge of the current barrier perpendicularly to the longitudinal central axis. The distance is preferably determined in the active zone. In other words, the distance is determined, for example, in the plane in which that surface of the active zone which faces the contact strip is situated. The distance is then determined between a projection of the contact strip into the plane and the inner edge of the current barrier.

The edge emitting semiconductor laser chip may comprise at least one contact strip, wherein the contact strip has a width B, an active zone in which electromagnetic radiation is generated during the operation of the semiconductor laser chip, at least two current barriers arranged on different sides of the contact strip and extending along the contact strip, wherein the distance between each of the two current barriers and the contact strip is chosen in such a way that the ratio of the largest distance V to the width B is V/B>1.0.

The ratio of the largest distance V to the width B may be V/B>1.2.

The ratio of the largest distance V to the width B may also be V/B>1.5.

The largest distance V may be situated at that side of the semiconductor laser chip at which a coupling-out facet of the semiconductor laser chip is situated. In this case, it is possible for the distance between at least one of the current barriers and the contact strip to increase with decreasing distance from the side at which the coupling-out facet of the semiconductor laser chip is situated. In other words, the current barrier runs, for example, along the contact strip, wherein its distance from the contact strip increases with decreasing distance from the side at which a coupling-out facet of the semiconductor laser chip is situated.

Two current barriers in each case may be arranged axially symmetrically with respect to the longitudinal central axis of a contact strip. In this case, the longitudinal central axis is that axis which extends from that side of the semiconductor laser chip at which the coupling-out facet is situated to that side of the semiconductor laser chip which is opposite the side, wherein the axis is arranged in the center of the contact strip. In this case, the longitudinal central axis can form an axis of symmetry of the contact strip. The current barriers are then arranged axially symmetrically with respect to the longitudinal central axis at two different sides of the contact strip. In this case, “axially symmetrically” means that the current barriers are arranged axially symmetrically within the scope of production tolerance. In this case, it is clear to the personthose skilled in the art that a strict axial symmetry in the mathematical sense cannot be achieved in real semiconductor laser chips.

The shape of the current barriers in a plane parallel to the extension plane of the contact strip may be adapted to a thermal lens induced in the semiconductor laser chip during the operation thereof. The extension plane of the contact strip is that plane into which the contact strip extends. It is, for example, parallel to that surface of the semiconductor laser chip to which the contact strip is applied. This can be the top side of the semiconductor laser chip, for example.

Heat loss arises during the operation of the edge emitting semiconductor laser chip. This heat loss generates temperature gradients in the semiconductor laser chip. In this case, an inhomogeneous temperature distribution forms in the semiconductor laser chip in such a way that the temperature has a local maximum where the laser light generated during operation is coupled out from the semiconductor laser chip—at the coupling-out facet. The refractive index of the semiconductor material from which the edge emitting semiconductor laser chip is formed is temperature-dependent such that the refractive index increases as the temperature increases. Therefore, a thermal converging lens arises in the region of the coupling-out facet and distorts the phase front of the electromagnetic radiation circulating in the resonator. In this case, the shape of the current barriers is chosen such that it follows the shape of the thermal lens in a plane parallel to the extension plane of the contact strip. In this way, the current barrier can influence the thermal lens. In other words, the distance between the current barrier and the contact strip increases in the direction of the coupling-out facet. As a result, the heating power during the operation of the semiconductor laser chip is distributed over a larger space in the region of the coupling-out facet, and the current density decreases. As a result, the temperature gradient in the semiconductor material becomes smaller and the thermal lens effect decreases.

The course of at least one of the current barriers may be step-like at least in places in a plane parallel to the extension plane of the contact strip. In other words, the current barrier does not run in a continuous fashion, but rather has jumps at a distance from the contact strip which impart a step-like course to the current barrier.

The semiconductor laser chip may have at least two contact strips. Electric current is injected into the active zone of the semiconductor laser chip via each of the contact strips of the semiconductor laser chip. Per contact strip, a spatially separate laser beam is generated in the edge emitting semiconductor laser chip such that the number of the laser beams corresponds to the number of contact strips. The edge emitting semiconductor laser chip then has a number of emitters corresponding to the number of contact strips, wherein the exit area of each emitter is situated at the coupling-out facet of the semiconductor laser chip.

The edge emitting semiconductor laser chip may furthermore comprise at least one contact strip which is structured. In other words, the contact strip is not embodied in homogeneous fashion, for example, as a metal layer having a uniform width and/or thickness, rather the contact strip has structures.

In this case, the contact strip is structured in such a way that a charge carrier injection into the active zone decreases toward a side of the semiconductor laser chip at which the coupling-out facet of the semiconductor laser chip is situated

In other words, the contact strip extends, for example, on the top side of the semiconductor laser chip in the emission direction of the laser radiation generated by the edge emitting semiconductor laser chip during operation. The contact strip extends, for example, from that side of the edge emitting semiconductor laser chip which is remote from the coupling-out facet to that side of the semiconductor laser chip at which the coupling-out facet of the semiconductor laser chip is situated. In this case, the contact strip is structured in such a way that, in regions of the contact strip in the vicinity of the coupling-out facet, less current is injected into the active zone than in regions of the contact strip which are far away from the coupling-out facet. The charge carrier injection into the active zone therefore decreases toward that side of the semiconductor laser chip at which the coupling-out facet of the semiconductor laser chip is situated.

The semiconductor laser chip may comprise an active zone, in which electromagnetic radiation is generated during the operation of the semiconductor laser chip. Furthermore, the edge emitting semiconductor laser chip comprises at least one structured contact strip, wherein the contact strip is structured in such a way that a charge carrier injection into the active zone decreases toward a side of the semiconductor laser chip at which a coupling-out facet of the semiconductor laser chip is situated.

The contact strip may be structured into regions of high and regions of low charge carrier injection. In other words, the contact strip has regions from which little current is injected into the active zone. In this case, it is possible that no current at all is injected into the active zone from these regions. These regions of the contact strip are the regions of low charge carrier injection. Furthermore, the contact strip has regions from which a higher current is injected into the active zone. From these regions, the active zone is energized, for example, approximately with the normal operating current density of the semiconductor laser chip. These regions are the regions of high charge carrier injection.

The contact strip, in a direction longitudinally with respect to the longitudinal central axis of the contact strip, may be structured into regions of high and regions of low charge carrier injection. By way of example, the contact strip runs from that side of the semiconductor laser chip which is remote from the coupling-out facet to that side of the semiconductor laser chip at which the coupling-out facet is situated. By way of example, the longitudinal central axis is parallel to the emission direction of the laser radiation generated by the semiconductor laser chip.

In the case of traversing the contact strip along the longitudinal central axis, the contact strip is structured into regions of high and regions of low charge carrier injection. In this case, the regions can each have, for example, a rectangular or differently shaped base area. In this way, the regions can be formed, for example, by strips having the same width as the contact strip.

The area proportion of the regions of high charge carrier injection may decrease with decreasing distance toward that side of the semiconductor laser chip at which a coupling-out facet of the semiconductor laser chip is situated. In this way, the charge carrier injection into the active zone decreases toward that side of the semiconductor laser chip at which the coupling-out facet of the semiconductor laser chip is situated. The area proportion relates, for example, to the total area of the contact strip.

The contact strip, in a direction transversely with respect to the longitudinal central axis of the contact strip, may be structured into regions of high and regions of low charge carrier injection. In other words, in the case of traversing the contact strip in a direction transversely with respect to the direction of the longitudinal central axis, that is to say, for example, perpendicularly to the longitudinal central axis, then regions of high and low charge carrier injection are traversed.

The area proportion of the regions of high charge carrier injection may decrease with decreasing distance toward the longitudinal central axis. This means that, in the center of the contact strip, in this way little or no electric current at all is injected into the active zone. In the outer regions of the contact strip, by contrast, more current than in the center of the contact strip is injected into the active zone. Preferably, a contact strip section structured in this way in a direction transversely with respect to the longitudinal central axis is situated in the vicinity of that side of the semiconductor laser chip at which the coupling-out facet of the semiconductor laser chip is situated. In other sections of the contact strip, which lie further away from the coupling-out facet, the contact strip can then be unstructured, for example, such that there a high current is injected into the active zone.

The area proportion of the regions of high charge carrier injection may decrease with decreasing distance toward the longitudinal central axis and also with decreasing distance toward that side of the semiconductor laser chip at which a coupling-out facet of the semiconductor laser chip is situated. This can be achieved, for example, by the regions of high charge carrier injection being formed by strips which extend along the longitudinal central axis of the contact strip and taper in the direction of the coupling-out facet.

The contact strip in a direction transversely with respect to the longitudinal central axis of the contact strip and also in a direction parallel to the longitudinal central axis of the contact strip may be structured into regions of high and regions of low charge carrier injection. This can be achieved, for example, by the contact strip being structured into regions of high and low charge carrier injection which extend along and transversely with respect to the longitudinal central axis of the contact strip.

The contact strip may consist of a first material in the regions of high charge carrier injection and of a second material in regions of low charge carrier injection. In this case, the first material is chosen in such a way that its contact resistance with respect to the semiconductor material of the edge emitting semiconductor laser chip to which the contact strip is applied is chosen to be less than the contact resistance of the second material. A structuring of the contact strip into regions of high and low charge carrier injection is realized in this way. By way of example, the first and the second material contain or consist of first and second metals. As a result, both the regions of high and the regions of low charge carrier injection have approximately the same thermal conductivity since both in each case consist of or contain metals. Consequently, the thermal conductivity does not vary spatially and so the heat dissipation from the semiconductor laser chip via the contact strip hardly varies or does not vary at all.

Furthermore, it is possible for the contact strip to have third, fourth and so on further regions formed from third, fourth and so on further materials. The magnitude of the charge carrier injection from these regions can then lie between the magnitude of the charge carrier injection from the regions comprising the first metal and the magnitude of the charge carrier injection from the regions comprising the second metal. This means that the contact strip then has regions of high charge carrier injection, regions of low charge carrier injection and regions in which the charge carrier injection lies between these two extreme values. A further, finer structuring and hence an even more accurate setting of the charge carrier injection into the active zone are made possible in this way.

Contact strips structured in the manner described here may be situated both on the top side and on the underside of the edge emitting semiconductor laser chip.

### BRIEF DESCRIPTION OF THE DRAWINGS

The edge emitting semiconductor laser chip described here is explained in greater detail below on the basis of examples and the associated figures.

FIG. 1 shows plotted measured values of the beam divergence in angular degrees against the output power of an edge emitting semiconductor laser chip.

FIG. 2 shows the coupling of laser radiation into a fiber-optic system on the basis of a schematic plan view.

FIG. 3A shows a simulated temperature distribution in an edge emitting semiconductor laser chip in a schematic perspective illustration.

FIG. 3B shows an edge emitting semiconductor laser chip described here in a schematic sectional illustration.

FIG. 4A shows a schematic illustration of the efficiency of edge emitting semiconductor laser chips.

FIG. 4B shows a schematic illustration of the horizontal beam divergence for edge emitting semiconductor laser chips.

FIGS. 5 to 27 show schematic plan views of examples of edge emitting semiconductor laser chips described herein with different configurations of the current barriers.

FIGS. 28 to 32 show schematic plan views of examples of edge emitting semiconductor laser chips described herein with different configurations of the contact strip.

FIGS. 33A and 33B show a further possibility for structuring the charge carrier injection on the basis of a schematic sectional illustration.

### DETAILED DESCRIPTION

In the representative examples and figures, identical or identically acting constituent parts are in each case provided with the same reference symbols. The elements illustrated should not be regarded as true to scale; but rather, individual elements may be illustrated with an exaggerated size to provide a better understanding.

Technical progress in the realization of fiber lasers and fiber-coupled lasers which enable outstanding beam quality and high achievable output powers allow the lasers to be used, for example, in new industrial applications such as “remote” welding. Edge emitting semiconductor laser diodes are usually used as the pump light source. They afford a very high efficiency in the conversion of the electrically expended power into useable radiation power in conjunction with high optical output power. On the other hand, however, they exhibit a high ellipticity of the far field. Efficient coupling of the laser radiation into the round fiber cross section of a fiber-optic system 103 can be achieved only with the aid of expensive micro-optical units 101 that are complicated to adjust (in this respect, also see FIG. 2). Simplification and improvement of the fiber coupling of the laser diodes would lead to more cost-effective and more reliable laser systems. The adjustment complexity of the micro-optical units is drastically reduced if the beam divergence were smaller at least in the horizontal direction (which is narrower anyway)—the so-called “slow-axis” direction—and the beam has to be greatly transformed for efficient fiber coupling only in the vertical direction—that is to say in the direction perpendicular to the plane in which, for example, the top side 1a of the semiconductor laser chip lies.

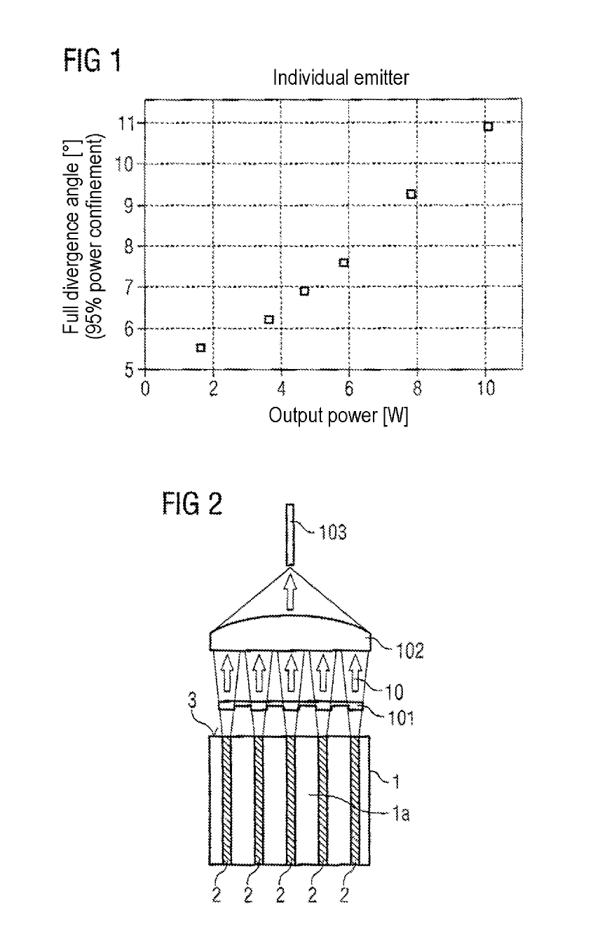

FIG. 1 shows plotted measured values of the beam divergence in angular degrees against the output power of an edge emitting semiconductor laser chip. The beam divergence was determined with 95% power confinement. The beam divergence was determined in the horizontal direction (slow-axis direction), that is to say in a plane which runs parallel to the top side 1a (in this respect, also cf. FIG. 2). “95% power confinement” means that only that region of the laser beam which confines 95% of the output power was taken into consideration for determining the beam divergence.

As can be seen from FIG. 1, the horizontal beam divergence increases greatly as the output power of the laser rises. This makes it more difficult to use the edge emitting semiconductor laser chips for high light powers as described above, since the small micro-optical units 101 preferably used can then be overly irradiated laterally and light is lost.

FIG. 2 shows the coupling of laser radiation 10, generated by an edge emitting semiconductor laser chip 1, into a fiber-optic system 103 on the basis of a schematic plan view. FIG. 2 shows an edge emitting semiconductor laser chip 1 embodied as a laser bar comprising five individual emitters. For this purpose, the edge emitting semiconductor laser chip has five contact strips 2 at its top side 1a. Five laser beams 10 are coupled out at the coupling-out facet 3, and firstly pass through a micro-optical unit 101. By a further optical element 102, which is a converging lens, for example, the laser radiation is combined and coupled into the fiber-optic system 103.

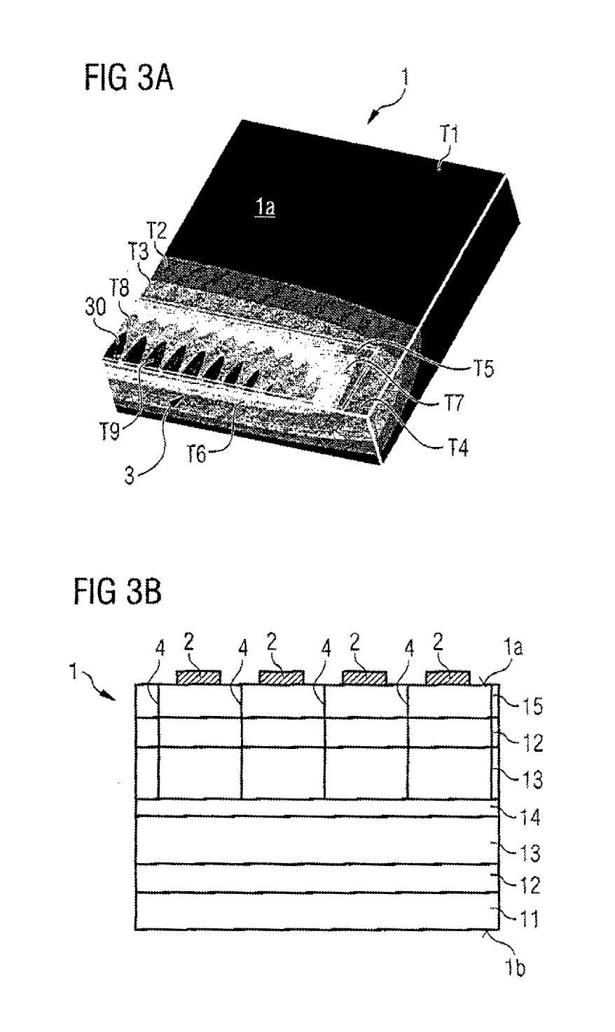

FIG. 3A shows, in a schematic perspective illustration, a simulated temperature distribution in an edge emitting semiconductor laser chip 1 embodied as a laser bar comprising 24 individual emitters. For reasons of symmetry, only half the bar with twelve emitters is shown in the illustration. The left-hand edge in FIG. 3A corresponds to the center of the laser bar. The dark locations in FIG. 3A symbolize regions 30 having a high temperature T9. The reference signs T1 to T9 mark temperature regions, where T1 identifies the region having the lowest temperature and T9 the region having the highest temperature.

The high dissipation power density in high-performance edge emitting semiconductor laser chips generates a temperature gradient in the semiconductor laser chip. As can be seen from FIG. 3A, in the case of high output powers of a number of watts and narrow strip widths of the individual emitters of the edge emitting semiconductor laser chip 1, an inhomogeneous temperature distribution forms in the resonator of the edge emitting semiconductor laser chip 1. In this case, local maxima of the temperature T9—the regions having a high temperature 30—are ascertained in the center of the coupling-out facet 3 of each individual emitter. This is also the case for edge emitting semiconductor laser chips having more or fewer emitters than in the laser in FIG. 3A or else for lasers having only a single emitter. Since the refractive index of the semiconductor material from which the semiconductor laser chip 1 is formed is temperature-dependent, a thermal converging lens arises in each emitter, and distorts the phase front of the laser light propagating in the resonator. As a result, the far field of the laser acts in expanded fashion in the horizontal (slow-axis) direction by comparison with the undistorted case. As the output power rises or as the pump current rises, the beam divergence thus rises owing to the phase front distortion that becomes greater with the power loss (in this respect, also cf. FIG. 1).

The maximum temperature attained and thus the strength of the thermal lens increases with the electrical power loss generated in the semiconductor laser chip 1. For the same optical output power, lasers having a higher efficiency generate less power loss in the semiconductor laser chip and generally exhibit smaller horizontal beam divergences.

FIG. 3B shows an edge emitting semiconductor laser chip 1 described in a schematic sectional illustration. The edge emitting semiconductor laser chip can be produced in different material systems. By way of example, a semiconductor laser chip based on one of the following semiconductor materials is involved: GAP, GaAsP, GaAs, GaAlAs, InGaAsP, GaN, InGaN, AlGaInAsSb. Moreover, further semiconductor materials from the III-V or II-VI semiconductor systems are also conceivable. Preferably, the semiconductor chip is based on the AlGaInAs material system, for example.

The edge emitting semiconductor laser chip 1 is, for example, a diode laser bar having a multiplicity of emitters, for example, having four to six emitters which has a resonator length of greater than or equal to 100 μm, for example, between 3 and 6 mm. The width of the laser radiation emitted by the individual emitters is preferably between 50 μm and 150 μm. The edge emitting semiconductor laser chip 1 can generate for example laser radiation having a central wavelength of 915 nm or 976 nm. However, depending on the semiconductor material used, the generation of shorter- or longer-wave laser light is also possible. Current barriers 4 can be situated between the contact strips 2, which current barriers restrict the impression of current into the active zone 14 in directions parallel to the emission direction of the semiconductor laser chip 1. In this case, it is also possible for two or more current barriers 4 to be situated between each two contact strips.

The semiconductor laser chip 1 comprises a substrate 11, which can be, for example, a growth substrate and which can form a p-type contact layer. Furthermore, the edge emitting semiconductor laser chip 1 comprises an active zone 14, which is provided for generating electromagnetic radiation. The active zone 14 is embedded into wave-guiding layers 13, which have a higher band gap and a lower refractive index than the active zone 14. The wave-guiding layers are each adjoined by a cladding layer 12 having a higher band gap and a lower refractive index than the wave-guiding layers 13. On that side of the semiconductor laser chip 1 which is remote from the substrate 11, a terminating contact layer 15 is situated on the cladding layer 12. Contact strips 2 are situated on the contact layer 15, via which contact strips electric current can be injected into the active zone 14. The width of the contact strips 2 is preferably between 10 μm and hundreds of μm. In this case, as shown in FIG. 3B, the current barriers 4 can extend as far as the active zone 14 or even right into the substrate 11.

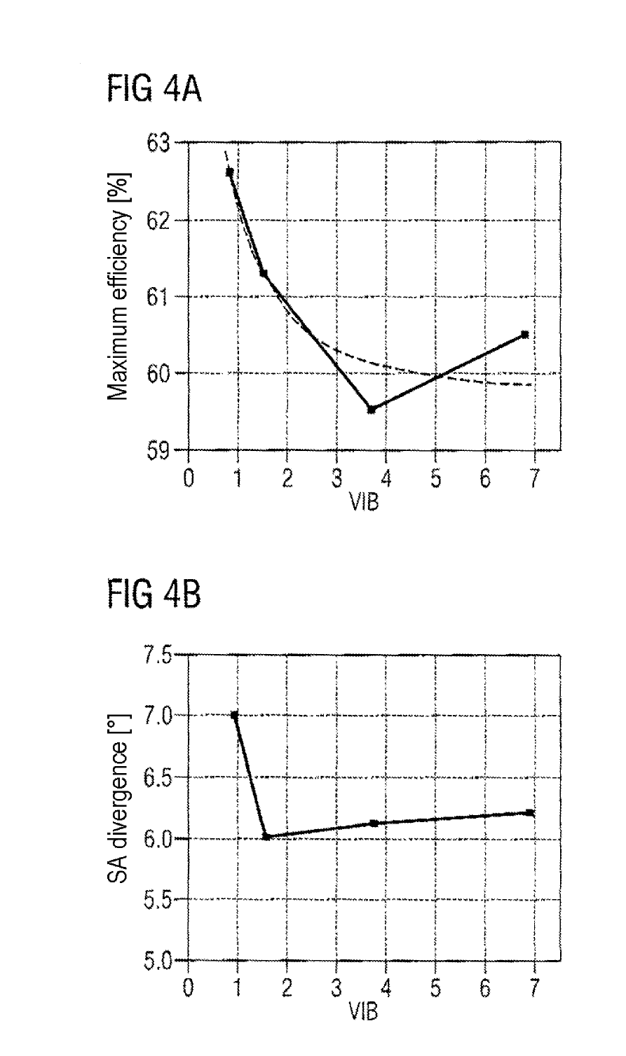

FIG. 4A shows a schematic illustration of the efficiency of an edge emitting semiconductor laser chip against the ratio of the largest distance V between at least one of the current barriers and the contact strip to the width B of the contact strip. The dashed line in FIG. 4A represents a trend line. The deviations can be explained by fluctuating measured values.

FIG. 4B shows a schematic illustration of the horizontal beam divergence given a power confinement of 95%, plotted against V/B for an edge emitting semiconductor laser chip having the same construction apart from the ratio V/B. A contact strip having a width of 70 μm is assumed in this case. The arrangement of the current barriers 4 with respect to the contact strip 2 in this case corresponds to the example described in conjunction with FIG. 5.

As can be gathered from FIG. 4A, the optimum of the efficiency lies in the range of small distances between current barriers and contact strip where V/B<1. On the other hand, an increased horizontal beam divergence (slow axis, SA beam divergence) occurs in this range of V/B (see FIG. 4B). Starting from a ratio V/B≈1.5, a saturation value of the divergence of approximately 6° is attained. In other words, with a targeted increase in the ratio V/B>1.0, preferably >1.2, a significantly smaller horizontal divergence is obtained with moderate impairment of the efficiency of the edge emitting semiconductor laser chip 1.

We discovered that the inhomogeneous temperature distribution in the edge emitting semiconductor laser chip can be partly compensated for by heating power in the marginal regions of the semiconductor laser chip 1, outside the emitter. This weakens the effect of the thermal lens, which leads to a reduced divergence of the laser radiation in the horizontal direction. As a result of an increased distance between the current barriers 4 and the contact strip 2, owing to the lateral current spreading the current density increases and thus so does the heating power in the outer region of the emitter, that is to say in the vicinity of the current barriers. In this case, the charge carrier injection is delimited in such a way that no charge carrier inversion is generated in the outer region. In other words, the current density in the vicinity of the current barriers does not suffice to result in laser activity. Only heat loss is generated in the vicinity of the current barriers, which lowers the efficiency of the component (cf. FIG. 4A). The ratio of the electrical power loss generated in the outer region to the electrical power loss generated in the effectively emitting region increases with increasing distance V between the current barriers 4 and the contact strip 2 owing to the increasing current-carrying area.

FIG. 5 shows an example of an edge emitting semiconductor laser chip described here in a plan view of the top side 1a of the edge emitting semiconductor laser chip 1. In this example, current barriers 4 are arranged axially symmetrically and parallel to the longitudinal central axis 23 of a contact strip 2, which is formed, for example, by a metalization onto the contact layer 15 of the semiconductor laser chip 1.

The current barriers are intended to prevent current spreading in the semiconductor layers between the active zone 14 and the contact strip 2. This can be realized in various ways.

Firstly, it is possible for trenches to be etched from the top side 1a, that is to say away from the contact layer 15, to at least below the active layer 14. These trenches are then preferably arranged between the individual emitters of the edge emitting semiconductor laser chip. These trenches suppress ring and transverse modes. The trenches need not necessarily be arranged axially symmetrically with respect to the contact strip 2. The etched sidewalls of the trenches can be covered with material suitable for absorbing the electromagnetic radiation generated in the active zone. U.S. Pat. No. 6,947,464, for example, describes an edge emitting semiconductor laser chip having such trenches.

A further possibility for producing current barriers 4 is implanting impurity atoms into the semiconductor and in this way destroying the electrical conductivity of the layers between the active zone and the contact strip in a targeted manner. In this case, it suffices to effect the implantation as far as the active zone 14.

In the example described in conjunction with FIG. 5, the laser facets are situated on the right and left in the figure. The coupling-out facet 3 is situated on the right-hand side.

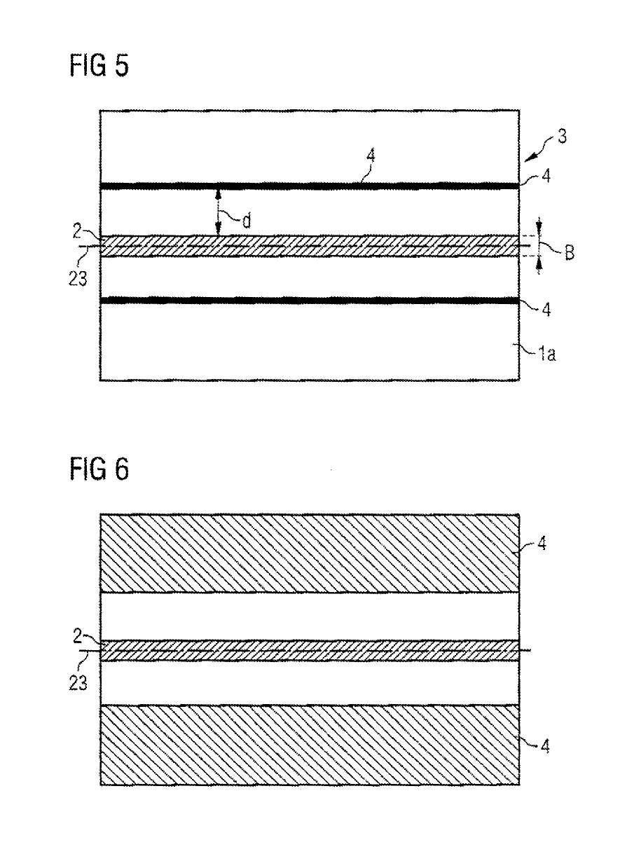

FIG. 6 shows a semiconductor laser chip described in accordance with one example in a schematic plan view. In this example, large-area current barriers 4 are applied axially symmetrically with respect to the longitudinal central axis 23 of the contact strip 2.

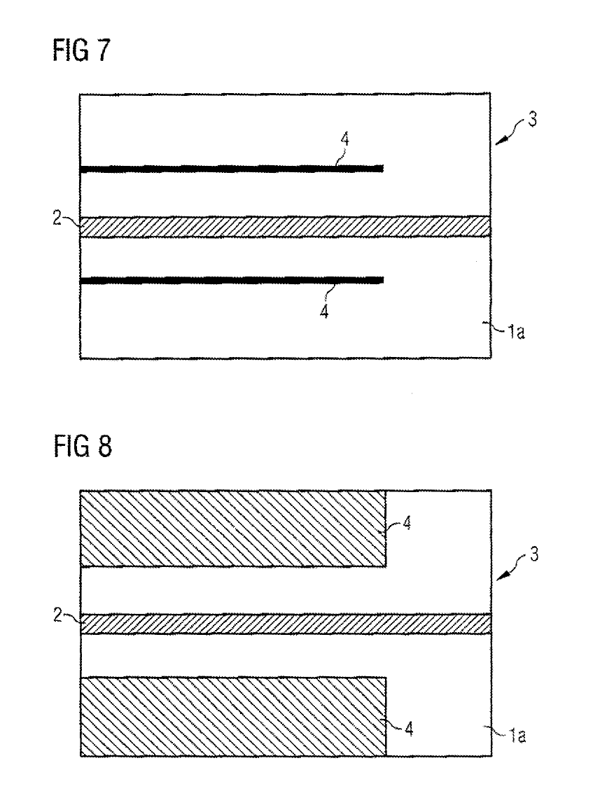

FIG. 7 shows, in schematic plan view, an example of an edge emitting semiconductor laser chip described here with symmetrically applied strip-type current barriers 4. The current barriers 4 in this case do not reach as far as the coupling-out facet 3. In this case, the distance from the coupling-out facet 3 can be up to a few millimeters. This produces, at the coupling-out facet 3, greater lateral current spreading and further homogenization of the temperature profile in the semiconductor laser chip. The effect of the thermal lens as described in conjunction with FIG. 3A can be reduced further in this way.

FIG. 8 shows a further example of an edge emitting semiconductor laser chip described here in a schematic plan view. In contrast to the example in FIG. 7, the current barriers are embodied in a large-area fashion.

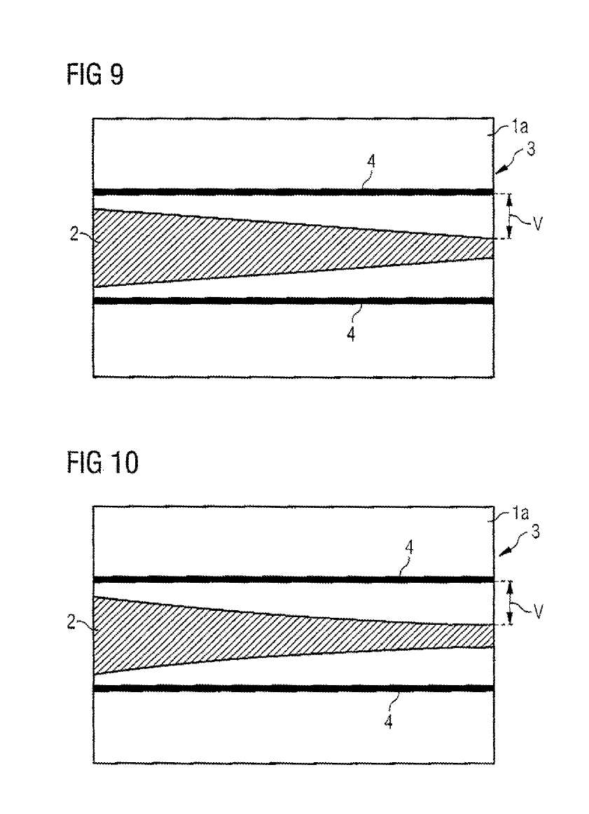

FIG. 9 shows an example of an edge emitting semiconductor laser chip described in which the distance between the current barrier 4 and the contact strip 2 increases as a result of a reduction of the contact strip width B in the direction of the coupling-out side 3. An increase in the lateral current spreading is likewise achieved in this way.

In conjunction with FIG. 10, an example of an edge emitting semiconductor laser chip described is shown in which, in contrast to the example in FIG. 9, the contact strip width is reduced non-linearly toward the coupling-out facet 3. Depending on the choice of the shape of the contact strip 2, it is possible to set a desired temperature profile in the semiconductor laser chip in this way.

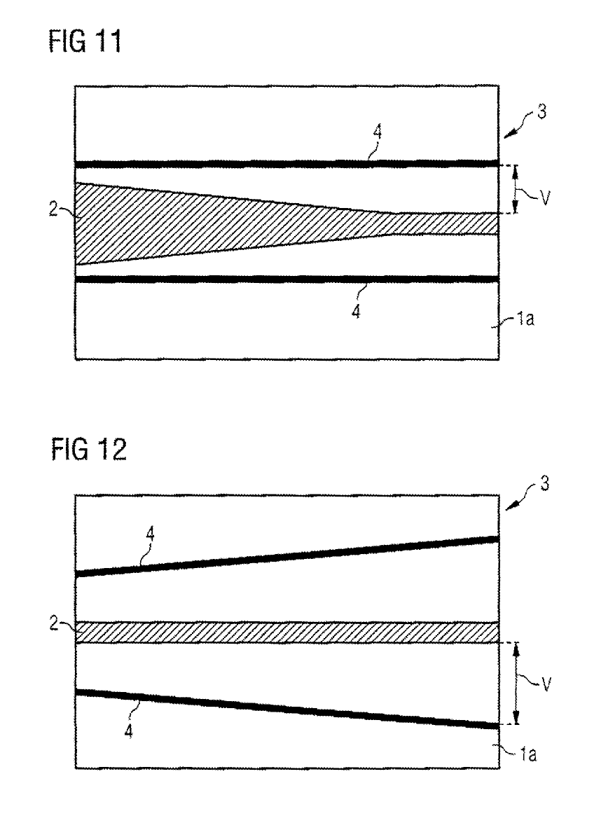

In conjunction with FIG. 11, an example of an edge emitting semiconductor laser chip described is described in which the distance between the current barrier 4 and the contact strip 2 is increased by variation of the contact strip width in regions of the semiconductor laser chip. The largest distance V is again situated in the vicinity of the coupling-out facet 3.

FIG. 12 shows an example of an edge emitting semiconductor laser chip described here in which the distance between the current barrier 4 and the contact strip 2 is increased linearly toward the coupling-out facet 3. The contact strip 2 has a constant width, whereas the distance between the current barriers 4 and the contact strip 2 is increased along a straight line. This leads to increased lateral current spreading and hence to homogenization of the temperature profile in the vicinity of the coupling-out facet 3.

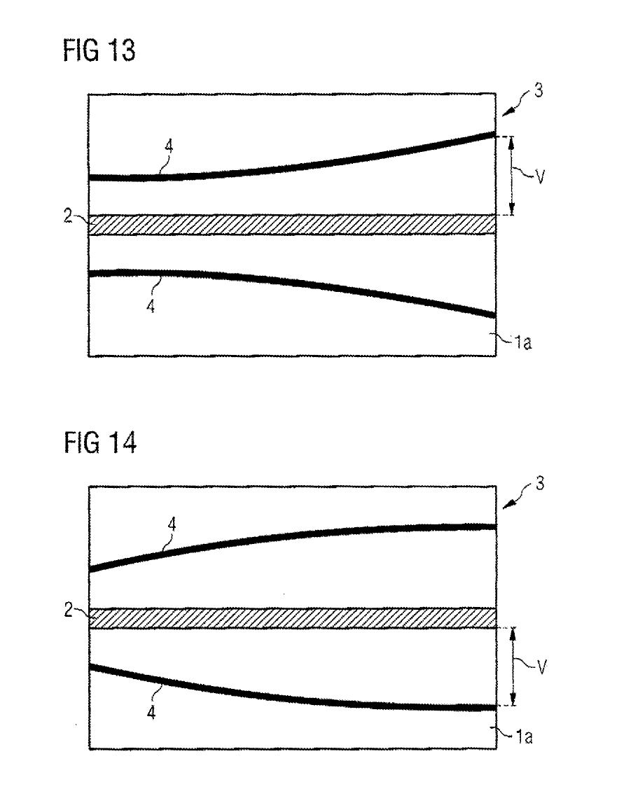

FIG. 13 shows an example of an edge emitting semiconductor laser chip described here in a schematic plan view in which, in contrast to the example in FIG. 12, a non-linear increase in the distance between the current barriers 4 and the contact strip 2 takes place.

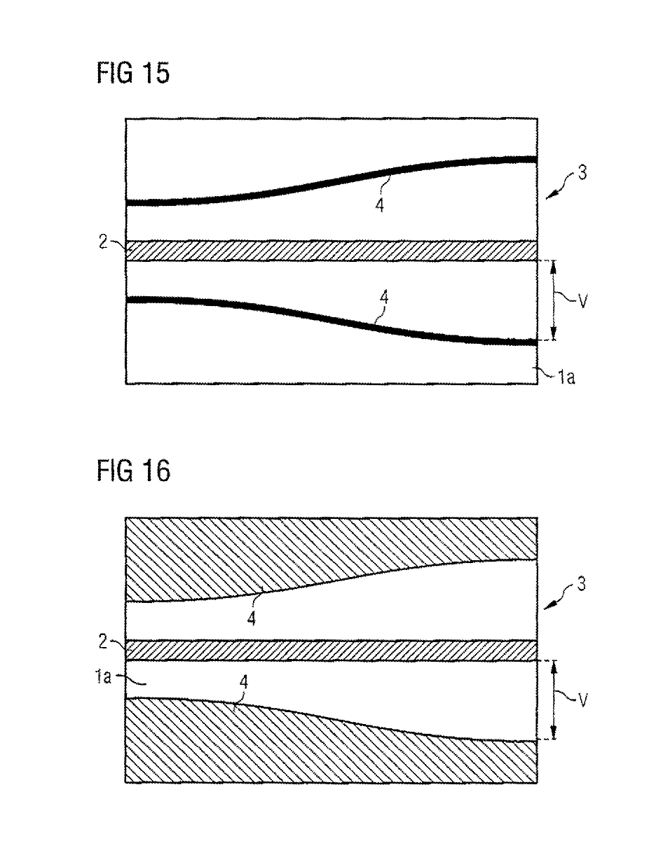

FIG. 14 shows, in a schematic plan view, an example of an edge emitting semiconductor laser chip described in which the course of the current barriers is tracked to the shape of the thermal lens such as can be seen from FIG. 3A, for example. In the examples of the edge emitting semiconductor laser chip described in conjunction with FIGS. 15 and 16, too, an adaptation of the distance between the current barriers 4 and the contact strip 2 to the thermal lens by a non-linear increase in the distance is shown. In this case, FIG. 16 shows a large-area current barrier.

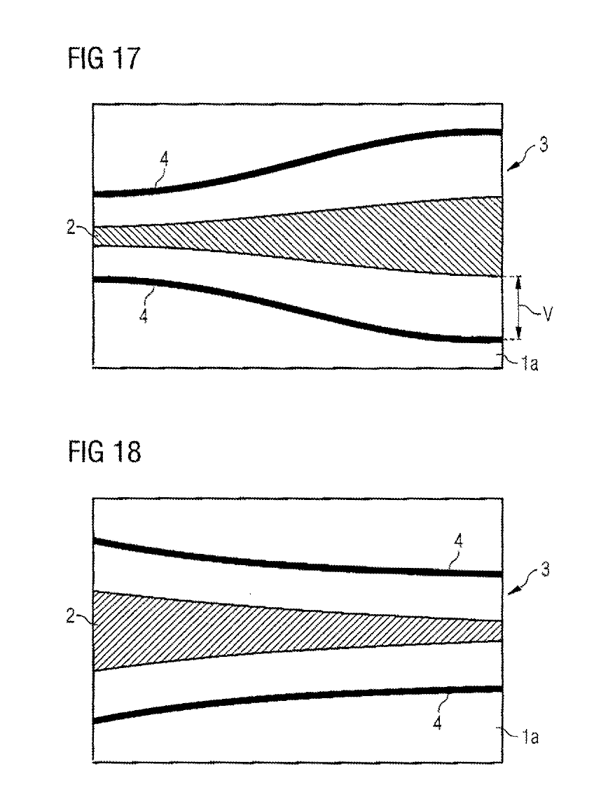

In the examples of the edge emitting semiconductor laser chip described in conjunction with FIGS. 17 and 18, the ratio V/B is increased in the direction of the coupling-out facet 3 with simultaneous variation of the contact strip width B and of the distance between the current barriers 4 and the contact strip 2.

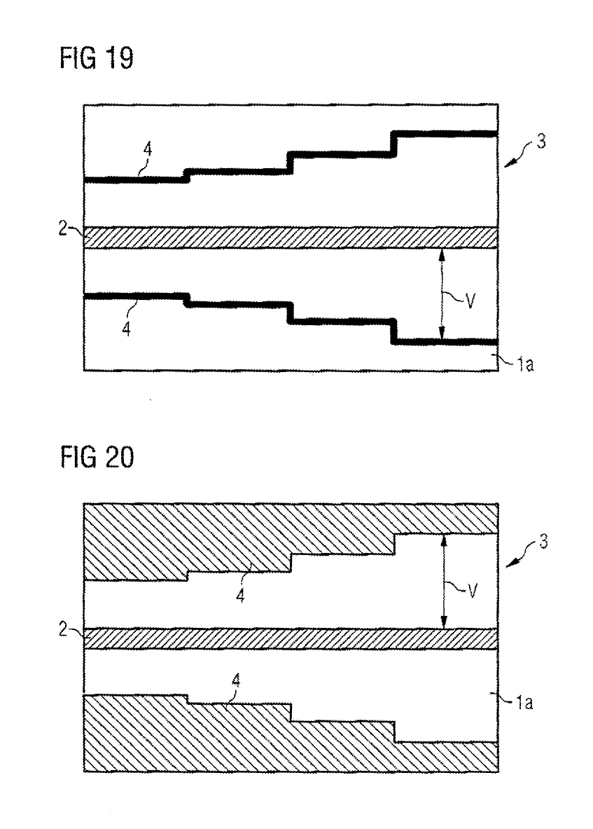

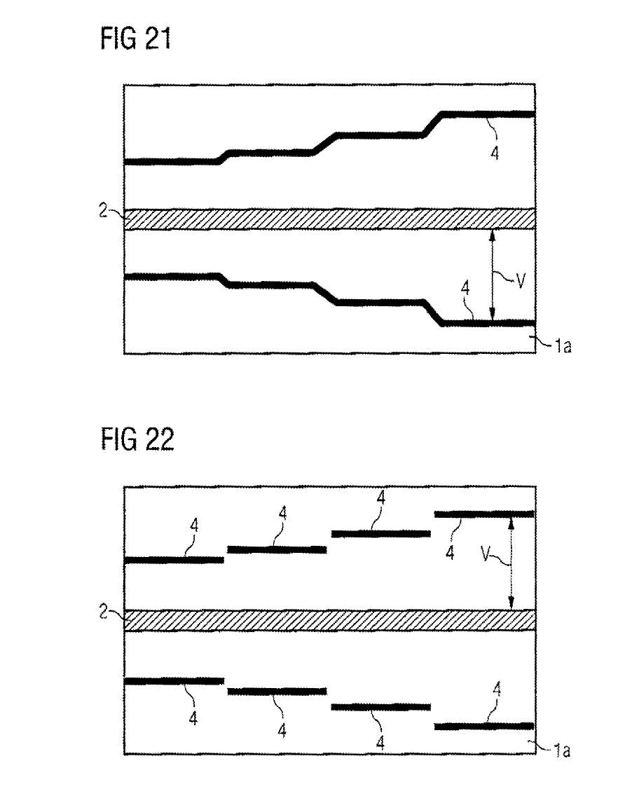

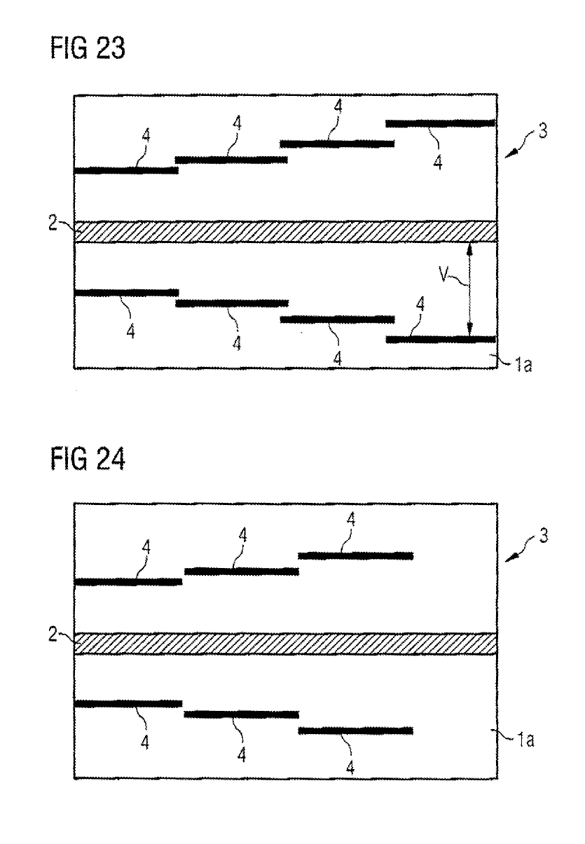

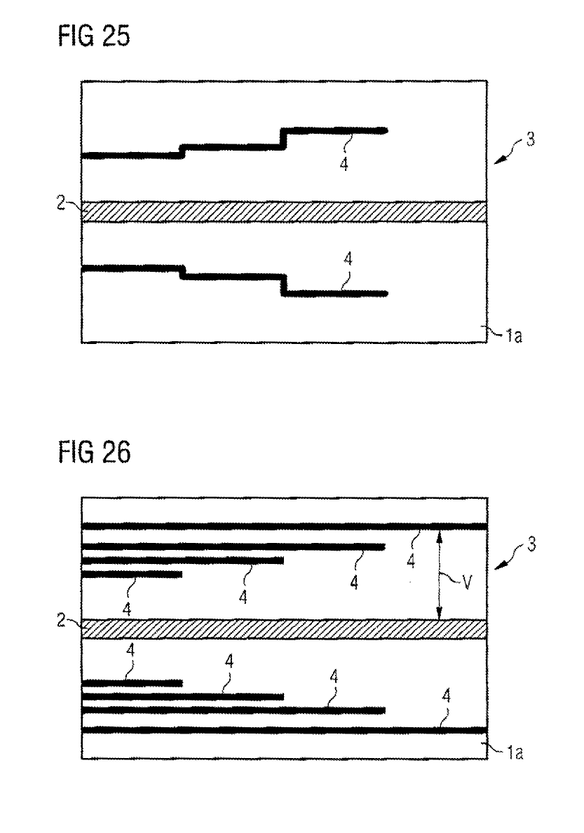

In the examples of an edge emitting semiconductor laser chip described here which are described in conjunction with FIGS. 19 to 26, the distance between contact strip 2 and current barriers 4 is changed discontinuously. As shown in FIGS. 22 to 24, it is also possible for the current barriers 4 to be composed of a plurality of current barriers which extend along the contact strip 2. Examples with and without an overlap of the individual current barriers are possible in this case. Current barriers having a discontinuous course afford the advantage that they can be produced in a particularly simple manner. Thus, problems can be avoided, for example, in the case of crystal direction-dependent etching rates during the etching of the current barriers. Furthermore, checking of the compliance with tolerances with respect to structures as described in conjunction with FIG. 10 by way of example, is facilitated.

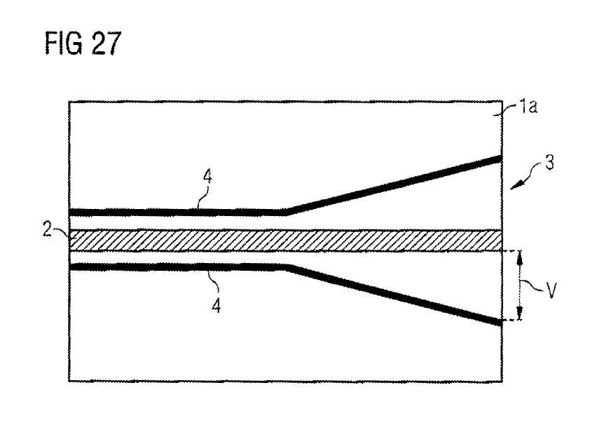

In conjunction with FIG. 27, an example of the edge emitting semiconductor laser chip is described in which the distance between current barrier 4 and contact strip 2 is increased only in the vicinity of the coupling-out facet 3. In the vicinity of the coupling-out facet 3 the ratio V/B can be ≧1.2, for example, whereas the ratio V/B in the remaining region of the semiconductor laser chip is <1. In this way, the ideal ratio for the efficiency of the semiconductor laser chip V/B<1, is utilized over a large part of the resonator (in this respect, also cf. FIG. 4a), whereas a larger ratio V/B is chosen only in the vicinity of the coupling-out facet 3, the larger ratio making it possible to reduce the effect of the thermal lens as described above.

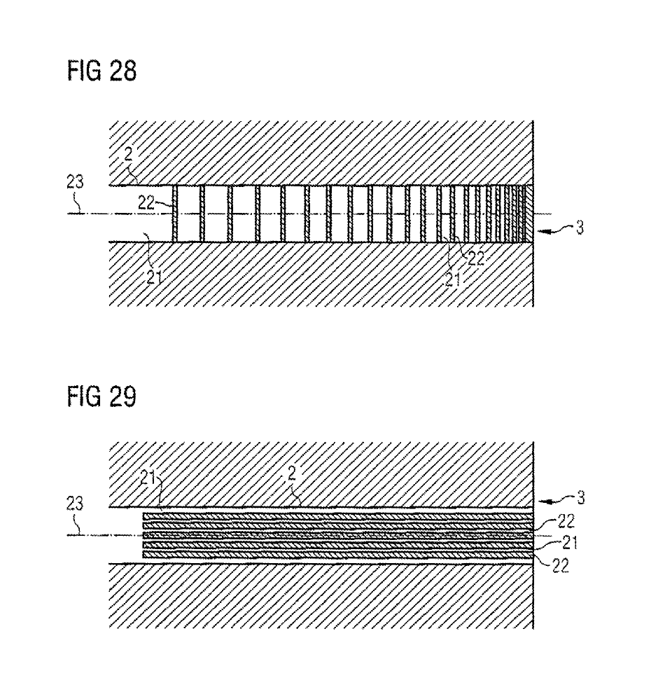

A further possibility for homogenizing the temperature profile at the coupling-out facet 3 of the semiconductor laser chip 1 and thus weakening the negative effect of the thermal lens to achieve a reduced beam divergence consists in structuring the contact strip 2. FIGS. 28 to 31 show possibilities for structuring the contact strip 2, which can be combined with any of the examples shown in FIGS. 5 to 27. In other words, the contact strips in FIGS. 5 to 27 can be exchanged for a contact strip as shown in FIGS. 28 to 31. This measure gives rise to semiconductor laser chips having particularly greatly reduced beam divergence in a horizontal direction.

FIG. 28 shows a contact strip 2 of an edge emitting semiconductor laser chip 1 described in a schematic plan view. The contact strip 2 can be situated at the top side 1a and/or at the underside 1b of the semiconductor laser chip 1. The contact strip 2 is structured in such a way that charge carrier injection into the active zone 14 decreases toward a side of the semiconductor laser chip 1 at which the coupling-out facet 3 of the semiconductor laser chip 1 is situated.

Structured current impression on the top side and/or underside of the semiconductor laser chip 1 leads by way of the associated likewise structured distribution of the resistive dissipation power density in the semiconductor laser chip 1 to a targeted influencing of the thermal lens in the resonator of the semiconductor laser chip 1. In this case, the resonator is formed by the coupling-out facet 3 and that side of the semiconductor laser chip 1 which is opposite the coupling-out facet 3. It proves to be particularly advantageous to structure the contact strip 2 in a longitudinal direction, that is to say in a direction along the longitudinal central axis 23 of the contact strip 2, and/or in a lateral direction, that is to say in a direction transversely or perpendicularly with respect to the longitudinal central axis 23 of the contact strip 2. This is because it has surprisingly emerged that in these cases, the temperature distribution is homogenized and this counteracts the distortion of the phase fronts on account of the thermal lens. This reduces the divergence of the laser beam generated in the emitter in a horizontal direction. The contact strip 2 is divided into regions of low charge carrier injection 22 and high charge carrier injection 21. Through the regions of low charge carrier injection 22, hardly any or no current at all is impressed into the active zone 14. By contrast, in the regions of high charge carrier injection 21, current is impressed into the active zone 14 in a manner similar to that in the unstructured case.

The structuring of the current impression can in this case be effected as follows:
One possibility for the structuring of the contact strip and, hence, the charge carrier injection is applying a correspondingly structured passivation layer to the semiconductor laser chip 1 in such a way that the passivation layer is removed only in the regions of high charge carrier injection 21, resulting in a contact between the material of the contact strip 2—usually a metal—and the semiconductor material of the semiconductor laser chip 1.
Furthermore, it is possible for the structuring to be produced by structured removal of the topmost semiconductor layer of the semiconductor laser chip 1 prior to application of the metallic layer of the contact strip 2 and, as a result, structuring of the contact resistance between the semiconductor material and the metal of the contact strip 2.
Furthermore, it is possible to effect a structured implantation or alloying-in of impurity atoms for alternating the contact resistance between the contact strip 2 and the semiconductor material of the semiconductor laser chip 1. As an alternative to the alteration of the contact resistance or in addition to the alteration of the contact resistance, the conductivity of the semiconductor material below the contact strip 2 can also be altered by implantation or alloying-in. In this way, too, the contact strip 2 is structured into regions of high and low charge carrier injection.
A further possibility for structuring the contact strip and, hence, the charge carrier injection is applying an n-doped semiconductor layer prior to the deposition of the contact strip 2 over the, for example, p-doped contact layer 15, the n-doped semiconductor layer then being removed again in structured fashion. In this way, at the locations where the n-doped layer is still present, during operation reverse-biased pn-diodes form, which effectively impede the current flow. Only where the n-doped layer has been removed can current then be injected. These regions form the regions of high charge carrier injection 21.
In the same way, a p-doped semiconductor layer can be applied above an n-doped contact layer 15, as a result of which the same effect occurs after the structured removal of the p-doped layer.
A further possibility for structuring the charge carrier injection is using quantum well intermixing to prevent the charge carrier recombination in the active zone 14 and, hence, the production of heat loss in the active zone 14 at these locations. By carrying out the quantum well intermixing in a structured manner, regions of high and low charge carrier injection into the active zone 14 can be produced in this way.
A further possibility for structuring the contact strip and, hence, the charge carrier injection is locally forming the contact strip 2 from different metals or other materials which have different electrical contact resistances at the interface between said materials and the contact layer 15 of the semiconductor laser chip. This, too, leads to structured charge carrier injection and division of the contact layer 2 into regions of high charge carrier injection 21 and regions of low charge carrier injection 22. This method simultaneously avoids a variation of the thermal conductivity of the contact strip 2 and, consequently, a variation of the heat dissipation from the semiconductor laser chip 1. A spatial modulation of the thermal lenses, which could impair the homogeneity of the laser light generated, is thereby avoided. By way of example, the contact layer 15 is in this case formed from p-doped GaAs. In regions of high current injection, the contact strip is then formed from Cr/Pt/Au, wherein Cr is the metal which is crucial for the low contact resistance. Aluminum, for example, is used in regions of low current injection.

In the example in FIG. 28, the charge carrier injection varies near the coupling-out facet 3 in a longitudinal direction, parallel to the longitudinal axis 23 of the contact strip 2. In this way, the temperature increase at the coupling-out facet 3 is reduced and the temperature distribution in the semiconductor laser chip 1 is balanced.

FIG. 29 shows the contact strip 2 of an edge emitting semiconductor laser described here. In this example, the charge carrier injection varies in a lateral direction, that is to say in a direction transversely with respect to the longitudinal axis 23. The structuring is preferably effected only in the vicinity of the coupling-out facet 3. No structuring is effected over the remaining length of the contact strip 2. The structuring locally minimizes the current density of the current impressed into the active zone in the center of the resonator of the semiconductor laser chip at the coupling-out facet 3. The structuring consists of regions of high charge carrier injection 21 and strip-like regions of low charge carrier injection 22, wherein particularly little current is injected in the center of the contact strip 2 and the area proportion of the regions of high charge carrier injection 21 is particularly small there. In other words, the relative proportion with respect to the total area or the ratio with respect to the adjacent regions of low charge carrier injection is particularly small there.

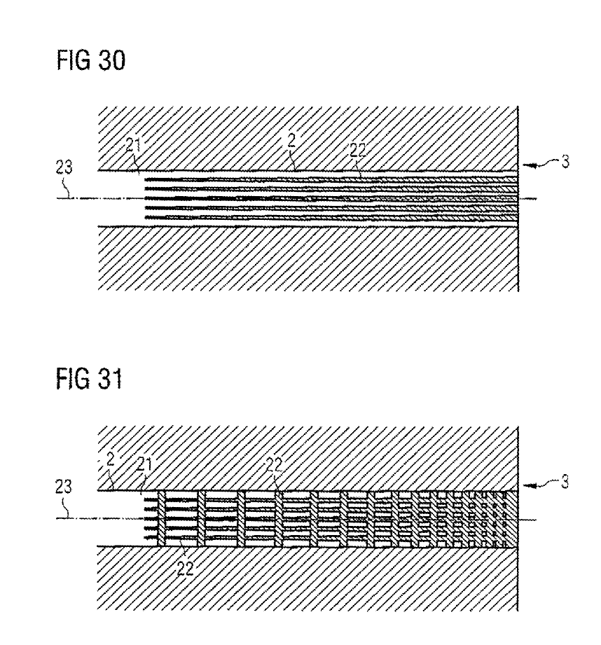

FIG. 30 shows the contact strip 2 of an edge emitting semiconductor laser chip 1. In this example, the current density in the active zone 14 is provided as a result of structuring of the contact strip 2 in longitudinal and lateral directions near the coupling-out facet 3 with a softer transition from the unstructured to the structured regions. The regions of high charge carrier injection 21 taper in the direction of the coupling-out facet 3, while the regions of low charge carrier injection 22 become wider in this direction.

FIG. 31 shows the contact strip 2 of an edge emitting semiconductor laser chip 1. In this example, the structuring measures of the contact strip 2 from the examples with respect to FIGS. 28 and 30 are combined. An even greater change in the current density injected into the active zone 14 is achieved in this way.

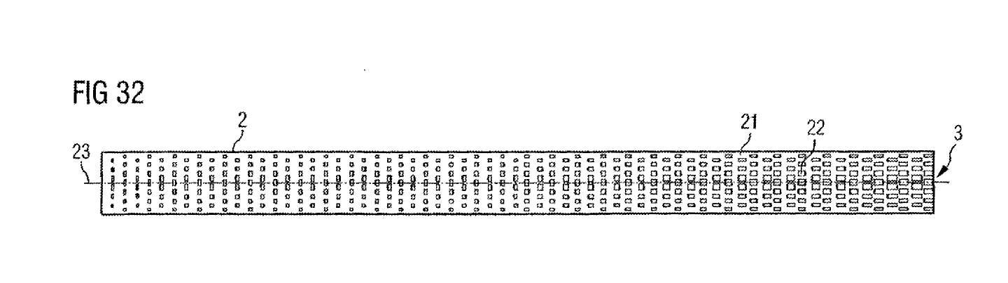

A halftone structuring of the contact strip 2 is described in conjunction with FIG. 32. The rectangles in FIG. 32 enclose regions of low charge carrier injection 22, that is to say that on average the injected current density decreases toward the coupling-out facet 3 and toward the central axis 23. In this case, the structuring is provided by one of the structuring measures described above. In other words, by way of example, a passivation layer can be present in the regions of low injection 22.

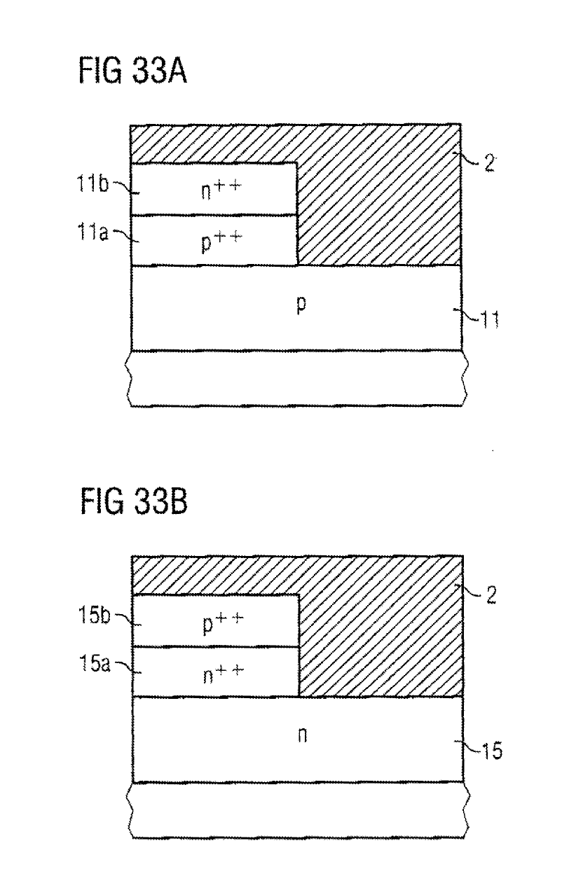

FIGS. 33A and 33B show a further possibility for structuring the charge carrier injection on the basis of a schematic sectional illustration through a part of the semiconductor laser chip 1.

The structuring of the contact strip 2 is effected by a tunnel contact. A very highly doped pn-junction particularly in the reverse direction forms a tunnel contact. With appropriate configuration, the tunnel contact can be ohmic, that is to say that it then has a linear current-voltage characteristic curve.

FIG. 33A illustrates that a highly p-doped tunnel layer 11a is applied to the p-type contact layer 11 of the semiconductor laser chip 1. The highly p-doped tunnel contact layer 11a is succeeded by a highly n-doped tunnel contact layer 11b. The tunnel contact layers are preferably applied to the p-type contact layer 11 over the whole area at least where a contact strip 2 is subsequently intended to be situated, and are removed in places after their epitaxy.

On account of the different electrical contact resistance between the metal of the contact strip 2 and n- and respectively p-doped semiconductors, a different charge carrier injection respectively arises in the regions with tunnel layers and the regions without tunnel layers. Regions of low charge carrier injection 22 and of high charge carrier injection 21 are therefore produced in this way.

In the case of poor contact between metal and p-doped semiconductor and good contact between metal and n-doped semiconductor, a high current density in the active zone arises in the region of the tunnel layers and a low current density arises in the region without tunnel layers. On the other hand, in the case of poor contact between metal and n-doped region and good contact between metal and p-doped region, a low current density, that is to say a region of low charge carrier injection 22, arises in the region of the tunnel layers and a high current density arises where the tunnel layers have been removed.

The same possibility for structuring also exists on the n-type side of the semiconductor laser chip 1. This is described in conjunction with FIG. 33B. A highly n-doped tunnel layer 15a is applied to the n-type contact layer 15 and a highly p-doped tunnel layer 15b is applied to the highly n-doped tunnel layer. In the case of poor contact between metal and p-doped region and good contact between metal and n-doped region, a low current density in the active zone arises where the tunnel layers were left, whereas a high current density arises where the tunnel layers were removed and there is a contact between the metal and the n-doped contact layer 15. Furthermore, in the case of poor contact between metal and the n-doped region and good contact between metal the p-doped region, a high current density arises in the region of the tunnel layers and a low current density arises where a metal to n-type contact was produced.

The disclosure is not restricted by the description on the basis of the examples. Rather, the disclosure encompasses any novel feature and also any combination of features, which in particular includes any combination of features in the patent claims, even if this feature or this combination itself is not explicitly specified in the patent claims or examples.

1. An edge emitting semiconductor laser chip comprising:
at least one contact strip (2) having a width B,
an active zone in which electromagnetic radiation is generated during operation of the semiconductor laser chip, and
at least two current barriers arranged on different sides of the contact strip and extending along the contact strip, wherein a largest distance V between each of the two current barriers and the contact strip is selected such that a ratio of the largest distance V to the width B is V/B>1.0.

2. The edge emitting semiconductor laser chip of claim 1,
wherein the largest distance V is situated in a vicinity of a side of the semiconductor laser chip at which a coupling-out facet of the semiconductor laser chip is situated.

3. The edge emitting semiconductor laser chip of claim 2,
wherein a distance between at least one current barrier and the contact strip increases with decreasing distance from a side at which the coupling-out facet is situated.

4. The edge emitting semiconductor laser chip of claim 1,
wherein the current barriers are arranged axially symmetrically with respect to a longitudinal central axis of the contact strip.

5. The edge emitting semiconductor laser chip of claim 1,
wherein shape of the current barriers in a plane parallel to an extension plane of the contact strip is adapted to a thermal lens induced in the semiconductor laser chip during operation thereof.

6. The edge emitting semiconductor laser chip of claim 5,
wherein the current barriers influence the thermal lens by shape.

7. The edge emitting semiconductor laser chip of claim 1,
wherein a course of at least one of the current barriers is step-like at least in places in a plane parallel to an extension plane of the contact strip.

8. The edge emitting semiconductor laser chip of claim 1, comprising at least two contact strips.

9. The edge emitting semiconductor laser chip of claim 2, comprising at least one structured contact strip structured such that a charge carrier injection into an active zone decreases toward a side of the semiconductor laser chip at which the coupling-out facet is situated, wherein the contact strip is structured into regions of high and regions of low charge carrier injection.

10. The edge emitting semiconductor laser chip of claim 9,
wherein an area proportion of the regions of high charge carrier injection decreases with decreasing, distance toward the side of the semiconductor laser chip at which a coupling-out facet is situated.

11. The edge emitting semiconductor laser chip of claim 1,
wherein the contact strip, in a direction transverse with respect to a longitudinal central axis of the contact strip is structured into regions of high and regions of low charge carrier injection, and wherein an area proportion of the regions of high charge carrier injection increases with increasing distance toward the longitudinal central axis.

12. The edge emitting semiconductor laser chip of claim 1,
wherein an area proportion of a regions of high charge carrier injection decreases with decreasing distance toward a longitudinal central axis of the contact strip and also with decreasing distance toward a side of the semiconductor laser chip at which a coupling-out facet of the semiconductor laser chip is situated.

13. The edge emitting semiconductor laser chip of claim 1,
wherein the contact strip in a direction transverse with respect to a longitudinal central axis and also in a direction parallel to the longitudinal central axis is structured into regions of high and regions of low charge carrier injection.

14. The edge emitting semiconductor laser chip of claim 1,
wherein the contact strip consists of a first metal in regions of high charge carrier injection and consists of a second metal in regions of low charge carrier injection, and wherein electrical contact resistance, with respect to semiconductor material to which the contact strip is applied, of the first metal is lower than that of the second metal.

15. The edge emitting semiconductor laser chip of claim 1,
wherein structured contact strip is applied on a top side and an underside of the semiconductor laser chip.
